(19) United States
(12) Patent Application Publication
(10) Pub. No.: US 2026/0229168 A1
(43) Pub. Date: Aug. 6, 2026

(54) BUFFER CIRCUIT, DISPLAY DEVICE AND ELECTRONIC DEVICE INCLUDING THE SAME

(71) Applicant: Samsung Display Co., Ltd., Yongin-si (KR)

(72) Inventors: Sang Hun KIM, Yongin-si (KR); Nack Hyeon KEUM, Yongin-si (KR); Jae Joong MIN, Yongin-si (KR); Seung Jun SHIN, Yongin-si (KR); Joo Young CHUN, Yongin-si (KR)

(21) Appl. No.: 19/408,053

(22) Filed: Dec. 3, 2025

(30) Foreign Application Priority Data
Jan. 31, 2025 (KR) 10-2025-0012653

(51) Int. Cl. G09G 3/32

(52) U.S. Cl. CPC G09G 3/32; G09G 2300/0426; G09G 2310/0267; G09G 2310/0275; G09G 2310/0291

(57) ABSTRACT

A buffer circuit includes: a pull-up transistor connected between a first voltage source and an output node; a pull-down transistor connected between the output node and a second voltage source; and at least one voltage boosting circuit configured to receive an input signal, to generate a boosting signal by amplifying an amplitude of the input signal, and to transmit the boosting signal to a gate electrode of the pull-down transistor.

### CROSS-REFERENCE TO RELATED APPLICATION

The present application claims priority to and the benefit of Korean Patent Application Number 10-2025-0012653, filed on January 31, 2025, in the Korean Intellectual Property Office, the entire disclosure of which is incorporated herein by reference.

### BACKGROUND

### 1. Field

Aspects of some embodiments of the present disclosure relate to a buffer circuit, a display device, and an electronic device including the same.

### 2. Description of Related Art

With the development of information technology, the importance of display devices, which provide a connection medium between users and information, has been emphasized. Owing to the importance of display devices, the use of various kinds of display devices, such as liquid crystal display devices, organic light-emitting display devices, and plasma display devices, has increased.

As display devices and display panels included therein become larger, the area occupied by scan drivers which apply a control signal to the display panel also increases. On the other hand, the length of the wiring for transmitting a clock signal applied to the scan driver is also increasing.

The above information disclosed in this Background section is only for enhancement of understanding of the background and therefore the information discussed in this Background section does not necessarily constitute prior art.

### SUMMARY

Aspects of some embodiments of the present disclosure include a buffer circuit, a display device, and an electronic device including the same, which may relatively reduce distortion of a clock signal transmitted to a scan driver compared to alternative systems.

A buffer circuit according to some embodiments of the present disclosure includes a pull-up transistor connected between a first voltage and an output node, a pull-down transistor connected between the output node and a second voltage, and at least one voltage boosting circuit receiving an input signal, generating a boosting signal by amplifying an amplitude of the input signal, and transmitting the boosting signal to a gate electrode of the pull-down transistor.

According to some embodiments, the pull-up transistor and the pull-down transistor may be P-type transistors.

According to some embodiments, the at least one voltage boosting circuit may include a charge pump circuit.

According to some embodiments, the at least one voltage boosting circuit may include a first transistor connected between the first voltage and a first node and having a gate electrode to receive the input signal, a second transistor connected between a second node and the second voltage and having a gate electrode to receive the input signal, a first capacitor connected between the first node and the second node, a third transistor connected between the first voltage and a third node and having a gate electrode to receive the input signal, a fourth transistor connected between the third node and the second node and having a gate electrode to receive the input signal, and a fifth transistor connected between the first node and the second voltage and having a gate electrode connected to the third node. The third node may be connected to the gate electrode of the pull-down transistor.

According to some embodiments, the first transistor, the second transistor, the third transistor, and the fifth transistor may be P-type transistors, and the fourth transistor may be an N-type transistor.

According to some embodiments, the at least one voltage boosting circuit may include a first voltage boosting circuit receiving the input signal and outputting a first boosting signal, and a second voltage boosting circuit receiving the first boosting signal and outputting a second boosting signal. The first boosting signal may be transmitted to a gate electrode of the pull-up transistor, and the second boosting signal may be transmitted to the gate electrode of the pull-down transistor.

According to some embodiments, the first voltage boosting circuit may include a first transistor connected between the first voltage and a first node and having a gate electrode to receive the input signal, a second transistor connected between a second node and the second voltage and having a gate electrode to receive the input signal, a first capacitor connected between the first node and the second node, a third transistor connected between the first voltage and a third node and having a gate electrode to receive the input signal, a fourth transistor connected between the third node and the second node and having a gate electrode to receive the input signal, and a fifth transistor connected between the first node and the second voltage and having a gate electrode connected to the third node. According to some embodiments, the third node may be connected to an input end of the second voltage boosting circuit.

According to some embodiments, the second voltage boosting circuit may include a sixth transistor connected between the first voltage and a fourth node and having a gate electrode connected to the third node, a seventh transistor connected between a fifth node and the second voltage and having a gate electrode connected to the third node, a second capacitor connected between the fourth node and the fifth node, an eighth transistor connected between the first voltage and a sixth node and having a gate electrode connected to the third node, a ninth transistor connected between the sixth node and the fifth node and having a gate electrode connected to the third node, and a 10th transistor connected between the fourth node and the second voltage and having a gate electrode connected to the sixth node. According to some embodiments, the sixth node may be connected to the gate electrode of the pull-down transistor.

According to some embodiments, the first transistor, the second transistor, the third transistor, the fifth transistor, the sixth transistor, the seventh transistor, the eighth transistor, and the 10th transistor may be P-type transistors, and the fourth transistor and the ninth transistor may be N-type transistors.

According to some embodiments, the buffer circuit may further include an inverter having an input end connected to the third node and an output end connected to a gate electrode of the pull-up transistor.

According to some embodiments, the buffer circuit may further include a third capacitor connected between the output node and the gate electrode of the pull-down transistor.

According to some embodiments, the input signal may include a first clock signal provided through a first input node and a second clock signal having a phase opposite to a phase of the first clock signal and provided through a second input node. According to some embodiments, the at least one voltage boosting circuit may include an 11th transistor connected between the second voltage and a seventh node and having a gate electrode connected to the second input node, a 12th transistor connected between the seventh node and the gate electrode of the pull-down transistor and having a gate electrode connected to the first input node, a 13th transistor connected between the first voltage and an eighth node and having a gate electrode connected to the second input node, a 14th transistor connected between the eighth node and the first input node and having a gate electrode connected to the first input node, a 15th transistor connected between the first voltage and the gate electrode of the pull-down transistor and having a gate electrode connected to the second input node, a fourth capacitor connected between the seventh node and the eighth node, and a fifth capacitor connected between the first input node and the gate electrode of the pull-down transistor.

According to some embodiments, the 11th to 15th transistors may be P-type transistors.

A display device according to some embodiments of the present disclosure includes a plurality of pixels, a scan driver connected to the plurality of pixels through a plurality of scan lines, a data driver connected to the plurality of pixels through a plurality of data lines which receive an image data signal and transmit a corresponding analog voltage, a driving controller controlling operations of the scan driver and the data driver, and providing a clock signal to the scan driver, and a buffer circuit compensating for distortion of the clock signal. According to some embodiments, the buffer circuit includes a pull-up transistor connected between a first voltage and an output node, a pull-down transistor connected between the output node and a second voltage, and at least one voltage boosting circuit receiving the clock signal, generating a boosting signal by amplifying an amplitude of the clock signal, and transmitting the boosting signal to a gate electrode of the pull-down transistor.

According to some embodiments, the at least one voltage boosting circuit may include a first transistor connected between the first voltage and a first node and having a gate electrode to receive the clock signal, a second transistor connected between a second node and the second voltage and having a gate electrode to receive the clock signal, a first capacitor connected between the first node and the second node, a third transistor connected between the first voltage and a third node and having a gate electrode to receive the clock signal, a fourth transistor connected between the third node and the second node and having a gate electrode to receive the clock signal, and a fifth transistor connected between the first node and the second voltage and having a gate electrode connected to the third node. According to some embodiments, the third node may be connected to the gate electrode of the pull-down transistor.

According to some embodiments, the at least one voltage boosting circuit may include a first voltage boosting circuit receiving the clock signal and outputting a first boosting signal, and a second voltage boosting circuit receiving the first boosting signal and outputting a second boosting signal. According to some embodiments, the first boosting signal may be transmitted to a gate electrode of the pull-up transistor, and the second boosting signal may be transmitted to the gate electrode of the pull-down transistor.

According to some embodiments, the first voltage boosting circuit may include a first transistor connected between the first voltage and a first node and having a gate electrode to receive the clock signal, a second transistor connected between a second node and the second voltage and having a gate electrode to receive the clock signal, a first capacitor connected between the first node and the second node, a third transistor connected between the first voltage and a third node and having a gate electrode to receive the clock signal, a fourth transistor connected between the third node and the second node and having a gate electrode to receive the clock signal, and a fifth transistor connected between the first node and the second voltage and having a gate electrode connected to the third node. According to some embodiments, the third node may be connected to an input end of the second voltage boosting circuit.

According to some embodiments, the second voltage boosting circuit may include a sixth transistor connected between the first voltage and a fourth node and having a gate electrode connected to the third node, a seventh transistor connected between a fifth node and the second voltage and having a gate electrode connected to the third node, a second capacitor connected between the fourth node and the fifth node, an eighth transistor connected between the first voltage and a sixth node and having a gate electrode connected to the third node, a ninth transistor connected between the sixth node and the fifth node and having a gate electrode connected to the third node, and a 10th transistor connected between the fourth node and the second voltage and having a gate electrode connected to the sixth node. According to some embodiments, the sixth node may be connected to the gate electrode of the pull-down transistor.

According to some embodiments, the buffer circuit may further include a third capacitor connected between the output node and the gate electrode of the pull-down transistor.

According to some embodiments, the clock signal may include a first clock signal provided through a first input node and a second clock signal having a phase opposite to a phase of the first clock signal and provided through a second input node. According to some embodiments, the at least one voltage boosting circuit may include an 11th transistor connected between the second voltage and a seventh node and having a gate electrode connected to the second input node, a 12th transistor connected between the seventh node and the gate electrode of the pull-down transistor and having a gate electrode connected to the first input node, a 13th transistor connected between the first voltage and an eighth node and having a gate electrode connected to the second input node, a 14th transistor connected between the eighth node and the first input node and having a gate electrode connected to the first input node, a 15th transistor connected between the first voltage and the gate electrode of the pull-down transistor and having a gate electrode connected to the second input node, a fourth capacitor connected between the seventh node and the eighth node, and a fifth capacitor connected between the first input node and the gate electrode of the pull-down transistor.

An electronic device according to some embodiments of the present disclosure includes a processor and a display device. According to some embodiments, the processor provides input image data. According to some embodiments, the display device displays an image based on the input image data. According to some embodiments, the display device includes a plurality of pixels, a scan driver connected to the plurality of pixels through a plurality of scan lines, a data driver connected to the plurality of pixels through a plurality of data lines which receive an image data signal and transmit a corresponding analog voltage, a driving controller controlling operations of the scan driver and the data driver, and providing a clock signal to the scan driver, and a buffer circuit compensating for distortion of the clock signal. According to some embodiments, the buffer circuit includes a pull-up transistor connected between a first voltage and an output node, a pull-down transistor connected between the output node and a second voltage, and at least one voltage boosting circuit receiving the clock signal, generating a boosting signal by amplifying an amplitude of the clock signal, and transmitting the boosting signal to a gate electrode of the pull-down transistor.

### BRIEF DESCRIPTION OF THE DRAWINGS

FIG. 1 is a diagram illustrating a display device according to some embodiments of the present disclosure.

FIG. 2 is a schematic diagram of an equivalent circuit of a pixel illustrated in FIG. 1 according to some embodiments of the present disclosure.

FIG. 3 is a block diagram of a scan driver according to some embodiments of the present disclosure.

FIG. 4A is a diagram schematically illustrating driving stages ST1 to STn shown in FIG. 6A and a transmission line of a first clock signal CLK1 input thereto according to some embodiments of the present disclosure.

FIG. 4B is a diagram showing waveforms of the first clock signal CLK1 measured at an input end of each of the driving stages shown in FIG. 4A according to some embodiments of the present disclosure.

FIG. 5A is a diagram illustrating embodiments in which a buffer circuit is connected in the middle of a transmission line of the first clock signal CLK1 according to some embodiments of the present disclosure.

FIG. 5B is a diagram showing waveforms of the first clock signal CLK1 measured at an input end of each of the driving stages shown in FIG. 5A according to some embodiments of the present disclosure.

FIG. 6A is a diagram showing current flow when clock signals of the same amplitude are applied to pull-up and pull-down transistors in an example of a buffer circuit according to some embodiments of the present disclosure.

FIG. 6B is a diagram showing waveforms of output signals during an operation of the buffer circuit according to the example shown in FIG. 6A according to some embodiments of the present disclosure.

FIG. 7A is a diagram showing current flow when clock signals of different amplitudes are applied to pull-up and pull-down transistors in an example of a buffer circuit according to some embodiments of the present disclosure.

FIG. 7B is a diagram showing waveforms of output signals during an operation of the buffer circuit according to the example shown in FIG. 7A according to some embodiments of the present disclosure.

FIG. 8A is a block diagram illustrating an example of a buffer circuit including a voltage boosting circuit according to some embodiments of the present disclosure.

FIG. 8B is a schematic diagram of an equivalent circuit of the voltage boosting circuit of FIG. 8A according to some embodiments of the present disclosure.

FIG. 9A is a block diagram illustrating an example of a buffer circuit including voltage boosting circuits according to some embodiments of the present disclosure.

FIG. 9B is a schematic diagram of an equivalent circuit of the voltage boosting circuit of FIG. 9A according to some embodiments of the present disclosure.

FIG. 10A is a block diagram illustrating an example of a buffer circuit including a voltage boosting circuit according to some embodiments of the present disclosure.

FIG. 10B is a schematic diagram of an equivalent circuit of an inverter of FIG. 10A according to some embodiments of the present disclosure.

FIG. 11A is a block diagram illustrating an example of a buffer circuit including a voltage boosting circuit according to some embodiments of the present disclosure.

FIG. 11B is a schematic diagram of an equivalent circuit of the voltage boosting circuit of FIG. 11A according to some embodiments of the present disclosure.

FIG. 12 is a block diagram of an electronic device according to some embodiments of the present disclosure.

FIG. 13 shows schematic diagrams of electronic devices according to some embodiments of the present disclosure.

### DETAILED DESCRIPTION

Hereinafter, aspects of some embodiments of the present disclosure will be described in more detail with reference to the attached drawings, such that those skilled in the art may easily implement the present disclosure. The present disclosure may be implemented in various forms, and is not limited to the embodiments to be described herein below.

In the drawings, portions which are not related to the present disclosure will be omitted in order to explain the present disclosure more clearly. Reference should be made to the drawings, in which similar reference numerals are used throughout the different drawings to designate similar components. Therefore, the aforementioned reference numerals may be used in other drawings.

For reference, the size of each component and the thickness of each component are arbitrarily represented for the sake of explanation, and embodiments according to the present disclosure are not limited to what is illustrated in the drawings. In the drawings, the thickness of each component may be exaggerated to clearly depict multiple layers and areas.

Furthermore, the expression “being the same” may mean “being substantially the same”. In other words, the expression “being the same” may include a range that may be tolerated by those skilled in the art. The other expressions may also be expressions from which “substantially” has been omitted.

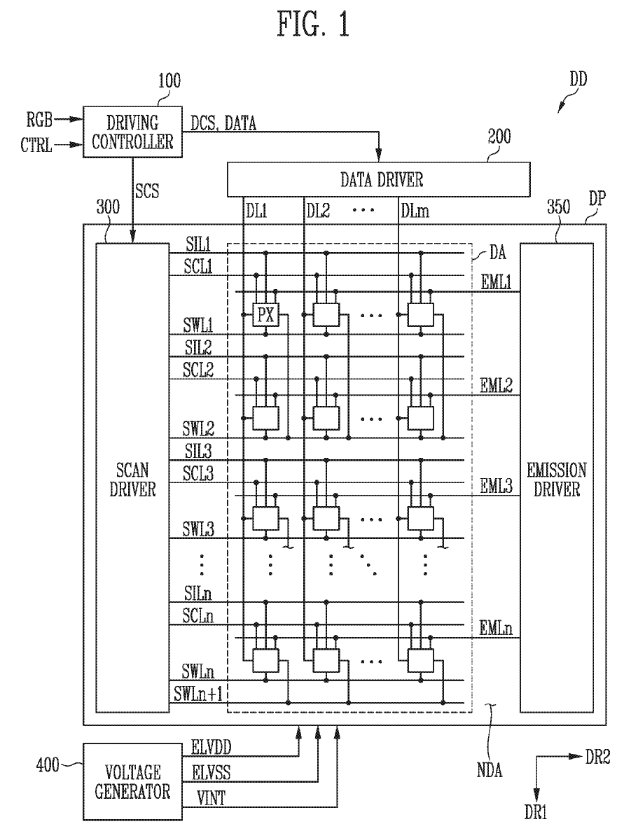

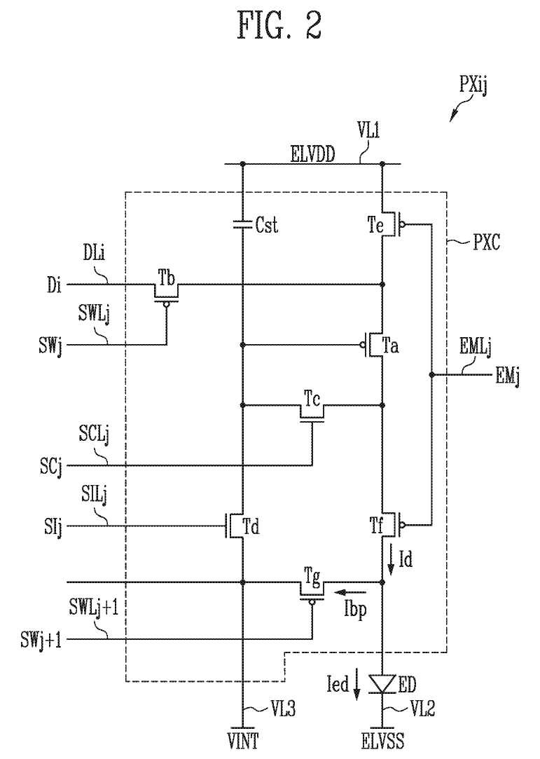

FIG. 1 is a diagram illustrating a display device DD according to some embodiments of the present disclosure. FIG. 2 is a schematic diagram of an equivalent circuit of a pixel illustrated in FIG. 1 according to some embodiments of the present disclosure. Although FIG. 2 illustrates various components in a pixel circuit according to some embodiments, embodiments according to the present disclosure are not limited thereto, and according to various embodiments, the pixel circuit may include additional components or fewer components without departing from the spirit and scope of embodiments according to the present disclosure.

Referring to FIGS. 1 and 2, the display device DD includes a display panel DP, a panel driver, and a driving controller 100. According to some embodiments of the present disclosure, the panel driver includes a data driver 200, a scan driver 300, an emission driver 350, and a voltage generator 400.

The driving controller 100 receives an image signal RGB and a control signal CTRL. The driving controller 100 generates an image data signal DATA obtained by converting the data format of the image signal RGB to meet the specifications for interfacing with the data driver 200. The driving controller 100 outputs a scan control signal SCS and a data control signal DCS.

The data driver 200 receives the data control signal DCS and the image data signal DATA from the driving controller 100. The data driver 200 converts the image data signal DATA into data signals, and outputs the data signals to a plurality of data lines DL1 to DLm to be described below. The data signals are analog voltages corresponding to a grayscale value of the image data signal DATA.

The scan driver 300 receives the scan control signal SCS from the driving controller 100. The scan driver 300 may output scan signals to scan lines in response to the scan control signal SCS.

The voltage generator 400 generates voltages necessary for an operation of the display panel DP. According to some embodiments, the voltage generator 400 generates a first driving voltage ELVDD, a second driving voltage ELVSS, and an initialization voltage VINT.

The display panel DP includes initialization scan lines SIL1 to SILn, compensation scan lines SCL1 to SCLn, write scan lines SWL1 to SWLn+1, emission control lines EML1 to EMLn, the data lines DL1 to DLm, and pixels PX. The initialization scan lines SIL1 to SILn, the compensation scan lines SCL1 to SCLn, the write scan lines SWL1 to SWLn+1, the emission control lines EML1 to EMLn, the data lines DL1 to DLm, and the pixels PX may overlap a display area DA. The initialization scan lines SIL1 to SILn, the compensation scan lines SCL1 to SCLn, the write scan lines SWL1 to SWLn+1, and the emission control lines EML1 to EMLn extend in a second direction DR2. The initialization scan lines SIL1 to SILn, the compensation scan lines SCL1 to SCLn, the write scan lines SWL1 to SWLn, and the emission control lines EML1 to EMLn are arranged spaced apart from each other in a first direction DR1. The data lines DL1 to DLm extend in the first direction DR1 and are arranged spaced apart from each another in the second direction DR2.

The plurality of pixels PX are electrically connected to the initialization scan lines SIL1 to SILn, the compensation scan lines SCL1 to SCLn, the write scan lines SWL1 to SWLn+1, the emission control lines EML1 to EMLn, and the data lines DL1 to DLm, respectively. Each of the plurality of pixels PX may be electrically connected to three scan lines. For example, as shown in FIG. 1, each of the pixels in the first row may be connected to the first initialization scan line SIL1, the first compensation scan line SCL1, and the first write scan line SWL1. In addition, each of the pixels of the second row may be connected to the second initialization scan line SIL2, the second compensation scan line SCL2, and the second write scan line SWL2.

The scan driver 300 may be arranged in a non-display area NDA of the display panel DP. The scan driver 300 receives the scan control signal SCS from the driving controller 100. The scan driver 300 may output initialization scan signals to the initialization scan lines SIL1 to SILn, output compensation scan signals to the compensation scan lines SCL1 to SCLn, and output write scan signals to the write scan lines SWL1 to SWLn+1 in response to the scan control signal SCS. The circuit configuration and operation of the scan driver 300 will be described in detail below.

The emission driver 350 may output emission control signals to the emission control lines EML1 to EMLn. According to some embodiments, the scan driver 300 may be connected to the emission control lines EML1 to EMLn. In this case, the scan driver 300 may output emission control signals to the emission control lines EML1 to EMLn.

Each of the plurality of pixels PX includes a light emitting diode ED and a pixel circuit portion PXC which controls emission of the light emitting diode ED. The pixel circuit portion PXC may include a plurality of transistors and a capacitor. The scan driver 300 may include transistors formed by the same process as the pixel circuit portion PXC.

Each of the plurality of pixels PX receives the first driving voltage ELVDD, the second driving voltage ELVSS, and the initialization voltage VINT from the voltage generator 400.

FIG. 2 shows an equivalent circuit of one pixel PXij of the plurality of pixels shown in FIG. 1. Because the plurality of pixels have the same circuit structure as each other, the description of the circuit structure of the pixel PXij would suffice for the remaining pixels other than one pixel PXij, and thus a detailed description of the remaining pixels is omitted. The pixel PXij is connected to the i-th data line DLi (hereinafter, referred to as a data line) among the data lines DL1 to DLm, the j-th initialization scan line SILj (hereinafter, referred to as an initialization scan line) among the initialization scan lines SIL1 to SILn, the j-th compensation scan line SCLj (hereinafter, referred to as a compensation scan line) among the compensation scan lines SCL1 to SCLn, the j-th and (j+1)-th write scan lines SWLj and SWLj+1 (hereinafter, referred to as first and second write scan lines) among the write scan lines SWL1 to SWLn, and the j-th emission control line EMLj (hereinafter, referred to as an emission control line) among the emission control lines EML1 to EMLn.

The pixel PXij includes the light emitting diode ED and the pixel circuit portion PXC. The pixel circuit portion PXC includes first to seventh transistors Ta, Tb, Tc, Td, Te, Tf, and Tg and one capacitor Cst. Each of the first to seventh transistors Ta to Tg may be a transistor having a low-temperature polycrystalline silicon (LTPS) semiconductor layer. One or more of the first to seventh transistors Ta to Tg may be P-type transistors, and the remaining transistors other than one or more transistors may be N-type transistors. For example, among the first to seventh transistors Ta to Tg, the first, second, and fifth to seventh transistors Ta, Tb, and Te to Tg may be P-type transistors, and the third and fourth transistors Tc and Td may be N-type transistors having an oxide semiconductor as a semiconductor layer. According to some embodiments, at least one of the first to seventh transistors Ta to Tg may be an N-type transistor and the remaining transistors other than at least one transistor may be a P-type transistor. The configuration of the pixel circuit portion PXC according to the present disclosure is not limited to the embodiments shown in FIG. 2. The pixel circuit portion PXC shown in FIG. 2 is merely an example, and the configuration of the pixel circuit portion PXC may be modified and implemented. For example, all of the first to seventh transistors Ta to Tg may be P-type transistors or N-type transistors.

The initialization scan line SILj, the compensation scan line SCLj, the first and second write scan lines SWLj and SWLj+1, and the emission control line EMLj may respectively transmit a j-th initialization scan signal SIj (hereinafter, referred to as an initialization scan signal), a j-th compensation scan signal SCj (hereinafter, referred to as a compensation scan signal), j-th and (j+1)-th write scan signals SWj and SWj+1 (hereinafter, referred to as first and second write scan signals), and a j-th emission control signal EMj (hereinafter, referred to as an emission control signal) to the pixel PXij. The data line DLi transmits a data signal Di to the pixel PXij. The data signal Di may have a voltage level corresponding to the image signal RGB input to the display device DD (see FIG. 1). First to third driving voltage lines VL1, VL2, and VL3 may respectively transmit the first driving voltage ELVDD, the second driving voltage ELVSS, and the initialization voltage VINT to the pixel PXij.

The first transistor Ta includes a first electrode connected to the first driving voltage line VL1 via the fifth transistor Te, a second electrode electrically connected to an anode of the light emitting diode ED via the sixth transistor Tf, and a gate electrode connected to one end of the capacitor Cst. The first transistor Ta may receive the data signal Di transmitted by the data line DLi according to the switching operation of the second transistor Tb, and supply a driving current Id to the light emitting diode ED.

The second transistor Tb includes a first electrode connected to the data line DLi, a second electrode connected to the first electrode of the first transistor Ta, and a gate electrode connected to the first write scan line SWLj. The second transistor Tb may be turned on according to the first write scan signal SWj transmitted through the first write scan line SWLj to transmit the data signal Di transmitted from the data line DLi to the first electrode of the first transistor Ta.

The third transistor Tc includes a first electrode connected to the gate electrode of the first transistor Ta, a second electrode connected to the second electrode of the first transistor Ta, and a gate electrode connected to the compensation scan line SCLj. The third transistor Tc may be turned on according to the compensation scan signal SCj received through the compensation scan line SCLj to connect the gate electrode and the second electrode of the first transistor Ta to each other to diode-connect the first transistor Ta.

The fourth transistor Td includes a first electrode connected to the gate electrode of the first transistor Ta, a second electrode connected to the third driving voltage line VL3 to which the initialization voltage VINT is transmitted, and a gate electrode connected to the initialization scan line SILj. The fourth transistor Td may be turned on according to the initialization scan signal SIj received through the initialization scan line SILj, transmit the initialization voltage VINT to the gate electrode of the first transistor Ta, and perform an initialization operation of initializing a voltage of the gate electrode of the first transistor Ta.

The fifth transistor Te includes a first electrode connected to the first driving voltage line VL1, a second electrode connected to the first electrode of the first transistor Ta, and a gate electrode connected to the emission control line EMLj.

The sixth transistor Tf includes a first electrode connected to the second electrode of the first transistor Ta, a second electrode connected to the anode of the light emitting diode ED, and a gate electrode connected to the emission control line EMLj.

The fifth transistor Te and the sixth transistor Tf are simultaneously turned on according to the emission control signal EMj received through the emission control line EMLj. The first driving voltage ELVDD applied through the turned-on fifth transistor Te may be compensated by the diode-connected first transistor Ta, and then transmitted to the light emitting diode ED.

The seventh transistor Tg includes a first electrode connected to the second electrode of the fourth transistor Td, a second electrode connected to the second electrode of the sixth transistor Tf, and a gate electrode connected to the second write scan line SWLj+1.

One end of the capacitor Cst is connected to the gate electrode of the first transistor Ta as described above, and the other end is connected to the first driving voltage line VL1. A cathode of the light emitting diode ED may be connected to the second driving voltage line VL2 which transmits the second driving voltage ELVSS.

When the high-level initialization scan signal SIj is provided through the initialization scan line SILj, the fourth transistor Td is turned on in response to the high-level initialization scan signal SIj. The initialization voltage VINT is transmitted to the gate electrode of the first transistor Ta through the turned-on fourth transistor Td, and the first transistor Ta is initialized by the initialization voltage VINT.

Next, when the high-level compensation scan signal SCj is supplied through the compensation scan line SCLj, the third transistor Tc is turned on. The first transistor Ta is diode-connected by the turned-on third transistor Tc and is biased forward. In addition, the second transistor Tb is turned on by the low-level first write scan signal SWj. Then, a compensation voltage (“Di-Vth”), which is obtained by reducing a threshold voltage (Vth) of the first transistor Ta from the data signal Di supplied from the data line DLi, is applied to the gate electrode of the first transistor Ta. That is, a potential of the gate electrode of the first transistor Ta may be the compensation voltage (“Di-Vth”).

The first driving voltage ELVDD and the compensation voltage (“Di-Vth”) are applied to opposite ends of the capacitor Cst, respectively, and a charge corresponding to a voltage difference between opposite ends may be stored in the capacitor Cst.

The seventh transistor Tg is turned on by receiving the low-level second write scan signal SWj+1 through the second write scan line SWLj+1. By the seventh transistor Tg, a portion of the driving current Id may exit through the seventh transistor Tg as a bypass current Ibp.

Next, the emission control signal EMj supplied from the emission control line EMLj is changed from the high level to the low level. The fifth transistor Te and the sixth transistor Tf are turned on by the low-level emission control signal EMj. Then, the driving current Id corresponding to a voltage difference between a gate voltage of the gate electrode of the first transistor Ta and the first driving voltage ELVDD is generated, and the driving current Id is supplied to the light emitting diode ED through the sixth transistor Tf, so that a current Ied flows through the light emitting diode ED.

As described above, the schematic diagram of the equivalent circuit of the pixel shown in FIG. 2 and a method of operating the same are provided as an example, and various circuits different from that shown in FIG. 2 may constitute the pixel PX of FIG. 1.

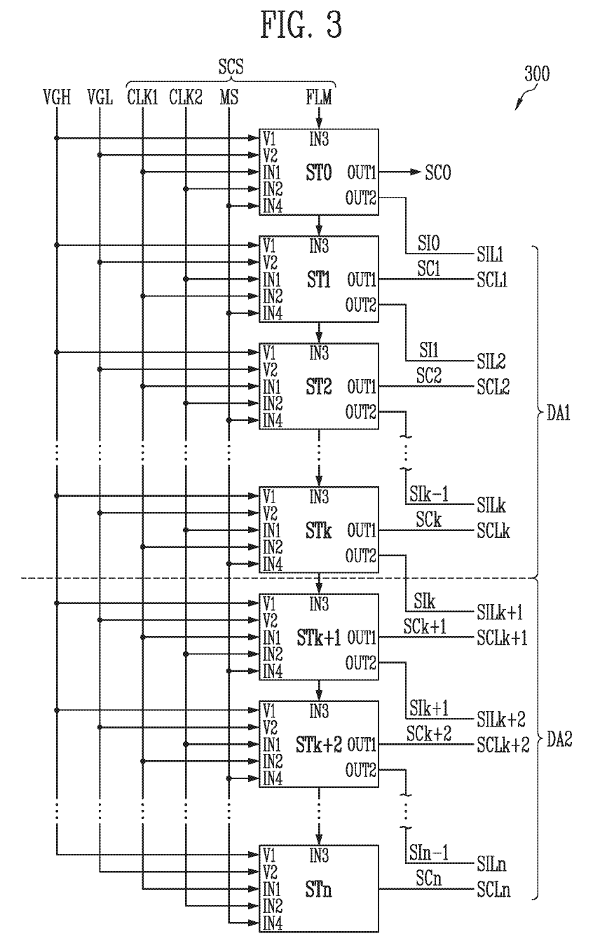

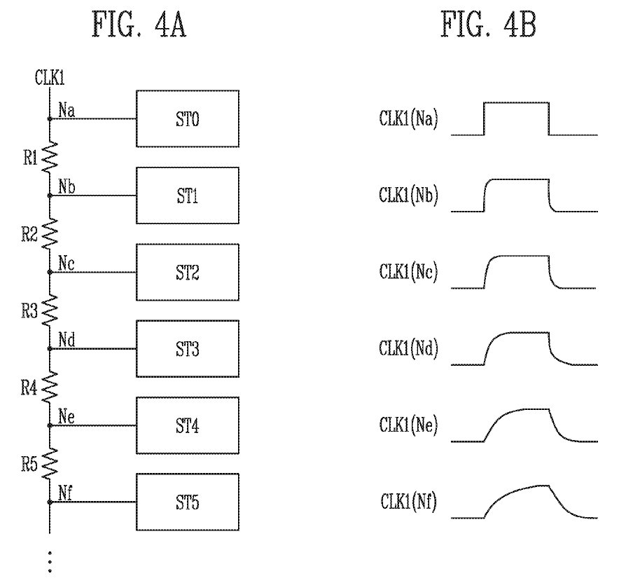

FIG. 3 is a block diagram of the scan driver 300 according to some embodiments of the present disclosure. Referring to FIG. 3, the scan driver 300 includes driving stages ST0 to STn. Each of the driving stages ST0 to STn receives the scan control signal SCS from the driving controller 100 shown in FIG. 1. The scan control signal SCS includes a start signal FLM, a first clock signal CLK1, a second clock signal CLK2, and a masking signal MS. Each of the driving stages ST0 to STn further receives a first voltage (or a first voltage source) VGH and a second voltage (or a second voltage source) VGL. The first voltage VGH and the second voltage VGL may be provided from the voltage generator 400 shown in FIG. 4. According to some embodiments, the first voltage VGH may be higher than the second voltage VGL. The second clock signal CLK2 may be a logically inverted signal of the first clock signal CLK1.

The masking signal MS may be a signal for masking scan signals (e.g., initialization scan signals) supplied to a second display area DA2 to a level (e.g., a set or predetermined level). As an example of the present disclosure, the masking signal MS may be provided to each of the driving stages ST0 to STn.

According to some embodiments, each of the driving stages ST0 to STn may have a first output terminal OUT1 which outputs a corresponding compensation scan signal and a second output terminal OUT2 which outputs a corresponding initialization scan signal.

A corresponding compensation scan line is connected to the first output terminal OUT1 of each of the driving stages ST1 to STn. Compensation scan signals SC1 to SCn among compensation scan signals SC0 to SCn are provided to the compensation scan lines SCL1 to SCLn, respectively. Specifically, the first output terminal OUT1 of the first driving stage ST1 among the driving stages ST1 to STn is connected to the corresponding first compensation scan line SCL1, to supply the first compensation scan signal SC1 to the first compensation scan line SCL1.

A corresponding initialization scan line may be connected to the second output terminal OUT2 of each of the driving stages ST0 to STn-1 among the driving stages ST0 to STn. The initialization scan signals SI0 to SIn-1 output from the second output terminals OUT2 of the driving stages ST0 to STn-1 are provided to the initialization scan lines SIL1 to SILn, respectively. Specifically, the second output terminal OUT2 of the first driving stage ST1 among the driving stages ST0 to STn-1 is connected to the corresponding second initialization scan line SIL2, and supplies the first initialization scan signal SI1 to the second initialization scan line SIL2. That is, as an example of the present disclosure, the first initialization scan signal SI1 may be supplied to the second initialization scan line SIL2 as a second initialization scan signal.

The first to k-th initialization scan lines SIL1 to SILk among the n initialization scan lines SIL1 to SILn are arranged in a first display area DA1, and the (k+1)-th to n-th initialization scan lines SILk+1 to SILn among the n initialization scan lines SIL1 to SILn are arranged in the second display area DA2, where each of n and k is an integer greater than or equal to 1, and n is greater than k. The first to k-th compensation scan lines SCL1 to SCLk among the n compensation scan lines SCL1 to SCLn are arranged in the first display area DA1, and the (k+1)-th to n-th compensation scan lines SCLk+1 to SCLn among the n compensation scan lines SCL1 to SCLn are arranged in the second display area DA2.

According to some embodiments the driving stages ST1 to STn may be connected to corresponding write scan lines, but embodiments according to the present disclosure are not limited thereto. That is, the scan driver 300 may further include driving stages for providing write scan signals to the write scan lines SWL1 to SWLn, respectively, in addition to the driving stages ST1 to STn.

The dummy driving stage ST0 among the driving stages ST0 to STn may receive the start signal FLM as a carry signal. Each of the driving stages ST1 to STn receives a carry signal from a previous driving stage. For example, the first driving stage ST1 receives a carry signal from the dummy driving stage ST0, and the second driving stage ST2 receives a carry signal from the first driving stage ST1. As an example of the present disclosure, the carry signal input to the second driving stage ST2 may be the same signal as the initialization scan signal SI1 output from the first driving stage ST1. That is, an initialization scan signal output from an immediately previous driving stage may be provided as a carry signal to each of the first to n-th driving stages ST1 to STn among the driving stages ST0 and STn. However, embodiments according to the present disclosure are not limited thereto. According to some embodiments, each of the driving stages ST1 to STn may be provided with an initialization scan signal output from one of previous driving stages as a carry signal.

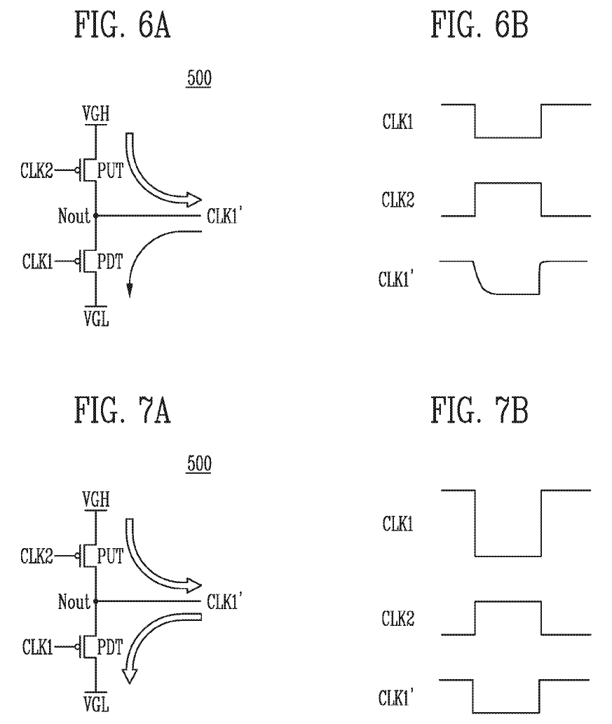

FIG. 4A is a diagram schematically illustrating the driving stages ST1 to STn shown in FIG. 6A and a transmission line of the first clock signal CLK1 input thereto according to some embodiments of the present disclosure. FIG. 4B is a diagram showing waveforms of the first clock signal CLK1 measured at an input end of each of the driving stages shown in FIG. 4A according to some embodiments of the present disclosure.

FIG. 4A illustrate the dummy driving stage ST0 and the first to fifth driving stages ST1 to ST5 shown in FIG. 3 are shown. The first clock signal CLK1 is applied to each of the driving stages. In FIG. 4A, illustrations of the start signal FLM, the second clock signal CLK2, the masking signal MS, the first voltage VGH, and the second voltage VGL are omitted. In addition, the illustration of signals output by each driving stage is also omitted.

The first clock signal CLK1 is supplied through a signal line connected in common to the driving stages ST0 to ST5. For example, the dummy driving stage ST0 and the first to fifth driving stages ST1 to ST5 may receive the first clock signal CLK1 through nodes Na, Nb, Nc, Nd, Ne, and Nf, respectively.

The signal line transmitting the first clock signal CLK1 may include a small resistance component. As the length of the signal line increases, the resistance component of the signal line may also increase. For example, there may be a first resistor R1 between the node Na and the node Nb, a second resistor R2 between the node Nb and the node Nc, a third resistor R3 between the node Nc and the node Nd, a fourth resistor R4 between the node Nd and the node Ne, and a fifth resistor R5 between the node Ne and the node Nf. Accordingly, the respective driving stages are affected by the resistance component from the side from which the first clock signal CLK1 is supplied. The farther the position of the driving stage is from the dummy driving stage ST0, the greater the driving stage is affected by the resistance component. As shown in FIG. 4A, there is the resistance component in the signal line itself which transmits the first clock signal CLK1, and according to some embodiments, there is also a parasitic capacitance component between the signal line transmitting the first clock signal CLK1 and another signal line, so that a waveform of the first clock signal CLK1 may be distorted depending on the position measured on the signal line.

FIG. 4B shows the waveforms of the first clock signal CLK1 measured at the nodes Na to Nf. In FIG. 4B, only one period of pulses of the first clock signal CLK1 which are periodically repeated is shown. Referring to FIG. 4B, because the resistance component between the node Na and the source of the first clock signal CLK1 may be seen as 0, the waveform of the first clock signal CLK1 at the node Na may have the form of an ideal square wave. On the other hand, as the resistance component between the corresponding node and the source of the first clock signal CLK1 increases in the direction away from the node Nb toward the node Nf, distortion due to an RC delay of the first clock signal CLK1 becomes severe.

As the display panel size and resolution of the display device increase, the number of scan drivers increases, which means that the length of the wiring which supplies the first clock signal CLK1 to each of the scan drivers increases. As the length of the wiring which supplies the first clock signal CLK1 increases, the degree of distortion of the first clock signal CLK1 at the distal end also increases. As the distortion of the first clock signal CLK1 increases, the operation timing of the driving stage may change, which may cause the timing of the signals output from the scan driver to deviate.

Although the signal distortion is described based on the first clock signal CLK1 with reference to FIGS. 4A and 4B, the second clock signal CLK2 and the masking signal MS may also be distorted in the same manner.

Accordingly, at least one buffer circuit may be arranged on the wiring which supplies the first clock signal CLK1 to minimize or reduce the distortion of the first clock signal CLK1 depending on the position in the wiring.

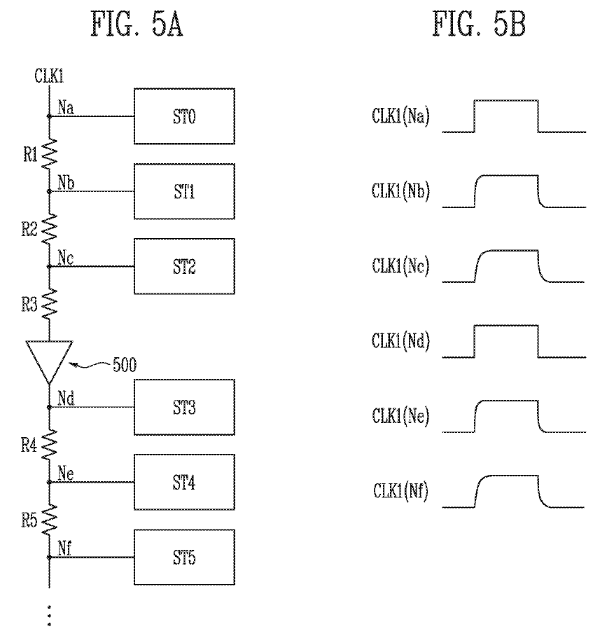

FIG. 5A is a diagram illustrating embodiments in which a buffer circuit 500 is connected in the middle of the transmission line of the first clock signal CLK1 according to some embodiments of the present disclosure. FIG. 5B is a diagram showing waveforms of the first clock signal CLK1 measured at an input end of each of the driving stages shown in FIG. 5A according to some embodiments of the present disclosure.

In an example of FIG. 5A, the buffer circuit 500 is connected between the node Nc and the node Nd. The buffer circuit 500 may receive a signal partially distorted by the RC delay, and output a signal close to an ideal square wave. Accordingly, as shown in FIG. 5B, it may be seen that the first clock signal CLK1 is distorted at each of the nodes Nb and Nc, but the first clock signal CLK1 at the node Nd connected to an output end of the buffer circuit 500 has the form of a square wave again. As described above, the distortion of the first clock signal CLK1 due to the RC delay may be compensated by arranging at least one buffer circuit at a necessary position on the wiring for transmitting the first clock signal CLK1.

FIG. 6A is a diagram showing current flow when clock signals of the same amplitude are applied to pull-up and pull-down transistors PUT and PDT in an example of the buffer circuit 500 according to some embodiments of the present disclosure. FIG. 6B is a diagram showing waveforms of output signals during an operation of the buffer circuit 500 according to the example shown in FIG. 6A according to some embodiments of the present disclosure.

Referring to FIG. 6A, a schematic diagram of an equivalent circuit of the buffer circuit 500 is shown. According to some embodiments, as shown in FIG. 6A, the buffer circuit 500 may include the pull-up transistor PUT and the pull-down transistor PDT connected between the first voltage VGH and the second voltage VGL. In the embodiments of FIG. 6A, the pull-up transistor PUT and the pull-down transistor PDT may each be a P-type transistor. The second clock signal CLK2 may be applied to a gate electrode of the pull-up transistor PUT, and the first clock signal CLK1 may be applied to a gate electrode of the pull-down transistor PDT. As described above, the first clock signal CLK1 and the second clock signal CLK2 may be clock signals of which phases are inverted from each other.

In FIG. 6B, the amplitudes of the first clock signal CLK1 and the second clock signal CLK2 are shown to be substantially the same. During a period in which the second clock signal CLK2 has a low-level voltage and the first clock signal CLK1 has a high-level voltage, the pull-up transistor PUT is turned on and the pull-down transistor PDT is turned off. Accordingly, a pull-up current is transmitted from the first voltage VGH side to a node Nout through the pull-up transistor PUT, and a voltage of the node Nout increases.

During a period in which the second clock signal CLK2 has the high-level voltage and the first clock signal CLK1 has the low-level voltage, the pull-up transistor PUT is turned off and the pull-down transistor PDT is turned on. Accordingly, a pull- down current is transmitted from the node Nout to the second voltage VGL side via the pull-up transistor PUT, and the voltage of the node Nout decreases. In this way, the voltage of the node Nout constitutes a first clock signal CLK1’ output from the buffer circuit 500.

Depending on the characteristics of the pull-up and pull-down transistors PUT and PDT, the rate at which the voltage of the node Nout rises when the pull-up transistor PUT is turned on may be different from the rate at which the voltage of the node Nout falls when the pull-down transistor PDT is turned on. For example, as indicated by the thicknesses of the arrows in FIG. 6A, when the pull-up transistor PUT is turned on, the voltage of the node Nout rises relatively quickly because a relatively great current flows through the pull-up transistor PUT, whereas when the pull-down transistor PDT is turned on, the voltage of the node Nout may fall relatively slowly because a relatively small current flows through the pull-down transistor PDT. Accordingly, as shown in FIG. 6B, the first clock signal CLK1’ output from the buffer circuit 500 may be distorted such that the falling time becomes longer than the rising time.

To prevent, reduce, or mitigate such distortion of the output signal, according to some embodiments of the present disclosure, the amplitude of a signal input to the gate electrode of the pull-down transistor PDT may be set to be great. This will be described with reference to FIGS. 7A and 7B.

FIG. 7A is a diagram showing current flow when clock signals of different amplitudes are applied to the pull-up and pull-down transistors PUT and PDT in an example of the buffer circuit 500 according to some embodiments of the present disclosure. FIG. 7B is a diagram showing waveforms of output signals during an operation of the buffer circuit 500 according to the example shown in FIG. 7A according to some embodiments of the present disclosure.

Referring to FIG. 7A, the current flowing from the output node Nout to the second voltage VGL side through the pull-down transistor PDT needs to be increased to rapidly lower the voltage of the output node NOUT.

To this end, as shown in FIG. 7B, according to some embodiments of the present disclosure, the amplitude of the first clock signal CLK1 applied to the gate electrode of the pull-down transistor PDT is set to be greater than the amplitude of the second clock signal CLK2 applied to the gate electrode of the pull-up transistor PUT. In this case, as shown in FIG. 7A, when the pull-down transistor PDT is turned on, the magnitude of the current flowing from the node Nout through the pull-down transistor PDT becomes greater, and thus the falling time of the first clock signal CLK1’ output from the buffer circuit 500 becomes shorter. Therefore, distortion of the first clock signal CLK1’ output from the buffer circuit 500 may be relatively reduced. To amplify the amplitude of the clock signal input to the gate electrode of the pull-down transistor PDT, the buffer circuit according to embodiments of the present disclosure may include at least one voltage boosting circuit.

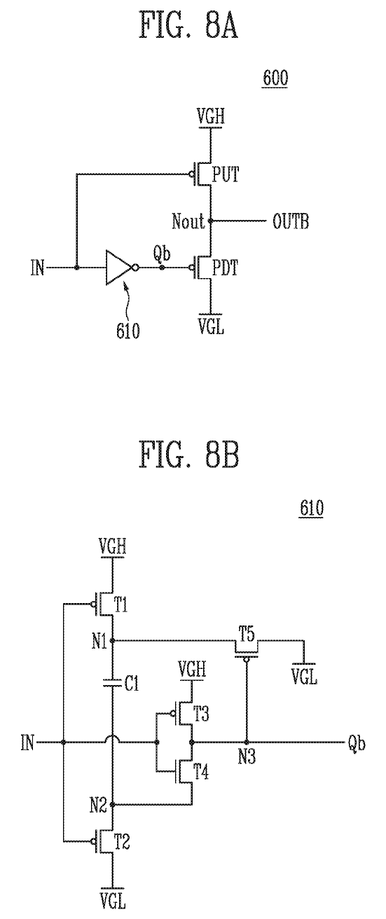

FIG. 8A is a block diagram illustrating aspects of an example buffer circuit 600 including a voltage boosting circuit 610 according to some embodiments of the present disclosure. FIG. 8B is a schematic diagram of an equivalent circuit of the voltage boosting circuit 610 of FIG. 8A according to some embodiments of the present disclosure. Although FIG. 8B illustrates various components in a voltage boosting circuit according to some embodiments, embodiments according to the present disclosure are not limited thereto, and according to various embodiments, the voltage boosting circuit may include additional components or fewer components without departing from the spirit and scope of embodiments according to the present disclosure.

Referring to FIG. 8A, the buffer circuit 600 according to some embodiments of the present disclosure includes the pull-up transistor PUT, the pull-down transistor PDT, and the voltage boosting circuit 610. The pull-up transistor PUT is connected between the first voltage VGH and the node Nout. The pull-down transistor PDT is connected between the node Nout and the second voltage VGL. The voltage of the node Nout constitutes an output signal OUTB.

An input signal IN is applied to an input end of the voltage boosting circuit 610. The input signal IN applied to the input end of the voltage boosting circuit 610 may also be input to the gate electrode of the pull-up transistor PUT. According to some embodiments, the input signal IN may be the first clock signal CLK1 or the second clock signal CLK2. However, embodiments according to the present disclosure are not limited thereto, and various other signals may be applied to the buffer circuit as the input signal IN.

An output end of the voltage boosting circuit 610 is connected to the gate electrode of the pull-down transistor PDT through a node Qb.

The voltage boosting circuit 610 may serve as an inverter in that the voltage boosting circuit 610 logically inverts the input signal IN. However, the voltage boosting circuit 610 may amplify the amplitude of the input signal IN and output the amplified signal to the gate electrode of the pull-down transistor PDT. Specifically, the voltage boosting circuit 610 may amplify the amplitude of the input signal IN to generate a boosting signal, and transmit the generated boosting signal to the gate electrode of the pull-down transistor PDT.

When the input signal IN is a high-level signal, the pull-up transistor PUT is turned off and the pull-down transistor PDT is turned on, so that the voltage of the node Nout becomes a low level. Conversely, when the input signal IN is a low-level signal, the pull-up transistor PUT is turned on and the pull-down transistor PDT is turned off, so that the voltage of the output node Nout becomes a high level. That is, the output signal OUTB composed of the voltage of the node Nout is a logically inverted signal of the input signal IN. When the input signal IN is the first clock signal CLK1, the output signal OUTB may be used as the second clock signal CLK2. On the other hand, when the input signal IN is the second clock signal CLK2, the output signal OUTB may be used as the first clock signal CLK1. According to some embodiments, an additional inverter may be provided at the node Nout shown in FIG. 8A, so that the final output signal is in phase with the input signal IN.

Referring to FIG. 8B, the voltage boosting circuit 610 may include first to fifth transistors T1 to T5 and a first capacitor C1. The first to third transistors T1 to T3 and the fifth transistor T5 among the first to fifth transistors T1 and T5 may be P-type transistors, and the fourth transistor T4 may be an N-type transistor. The first transistor T1 is connected between the first voltage VGH and a first node N1, and may receive the input signal IN through a gate electrode. The first capacitor C1 may be connected between the first node N1 and a second node N2. The second transistor T2 is connected between the second node N2 and the second voltage VGL, and may receive the input signal IN through a gate electrode. The third transistor T3 is connected between the first voltage VGH and a third node N3, and may receive the input signal IN through a gate electrode. The fourth transistor T4 is connected between the third node N3 and the second node N2, and may receive the input signal IN through a gate electrode. The fifth transistor T5 is connected between the first node N1 and the second voltage VGL, and a gate electrode may be connected to the third node N3. The third node N3 may be the same node as the node Qb shown in FIG. 8A, and may be connected to the gate electrode of the pull-down transistor PDT.

When the input signal IN is a low-level voltage, the first and second transistors T1 and T2 are turned on. Accordingly, a voltage of the first node N1 becomes the first voltage VGH, and a voltage of the second node N2 becomes the second voltage VGL. Therefore, the voltage difference between opposite ends of the first capacitor C1 is a value of “VGH-VGL”. When the input signal IN is a low-level voltage, the third transistor T3 is turned on and the fourth transistor T4 is turned off. Therefore, a voltage of the third node N3 becomes the first voltage VGH and the fifth transistor T5 is turned off. That is, when the input signal IN is at the low level, a voltage of the node Qb is the first voltage VGH.

When the input signal IN is switched from a low-level voltage to a high-level voltage, the first and second transistors T1 and T2 are turned off. The voltage difference between opposite ends of the first capacitor C1 maintains a value of “VGH-VGL”, and the third transistor T3 is turned off and the fourth transistor T4 is turned on because the input signal IN has been switched to a high-level voltage. Therefore, the voltage of the third node N3 becomes the second voltage VGL, and the fifth transistor T5 is turned on. As the fifth transistor T5 is turned on, the voltage of the first node N1 becomes the second voltage VGL. Because the voltage difference between opposite ends of the first capacitor C1 maintains the value of “VGH-VGL”, the voltage of the second node N2 becomes a value of “2VGL-VGH”. Because the fourth transistor T4 is in a turn-on state, the voltage of the third node N3 changes from the second voltage VGL to a value of “2VGL-VGH”. That is, the voltage of the node Qb becomes “2VGL-VGH”. The voltage of the node Qb constitutes a boosting signal, and the boosting signal output to the node Qb is transmitted to the gate electrode of the pull-down transistor PDT.

Consequently, when the input signal IN swings between the first voltage VGH and the second voltage VGL, the voltage of the node Qb, i.e., a voltage of the boosting signal, swings between the first voltage VGH and the value of “2VGL-VGH”. The amplitude of the input signal IN is “VGH-VGL” and the amplitude of the node Qb is “2VGH-2VGL”. In other words, the voltage boosting circuit 610 of FIG. 8B generates the boosting signal which doubles the amplitude of the input signal. As shown in FIG. 8B, the voltage boosting circuit 610 may be implemented as a charge pump circuit using the first capacitor C1. However, embodiments according to the present disclosure are not limited thereto, and the voltage boosting circuit 610 may be implemented in various ways other than the charge pump circuit.

Referring to FIGS. 8A and 8B together, the input signal IN is applied to the gate electrode of the pull-up transistor PUT without amplification. On the other hand, the boosting signal input to the gate electrode of the pull-down transistor PDT is a signal having an amplitude twice the amplitude of the input signal IN and an opposite phase to the input signal IN. Therefore, because the boosting signal with the amplified amplitude is applied to the gate electrode of the pull-down transistor PDT, distortion of the signal OUTB of the node Nout is minimized or reduced.

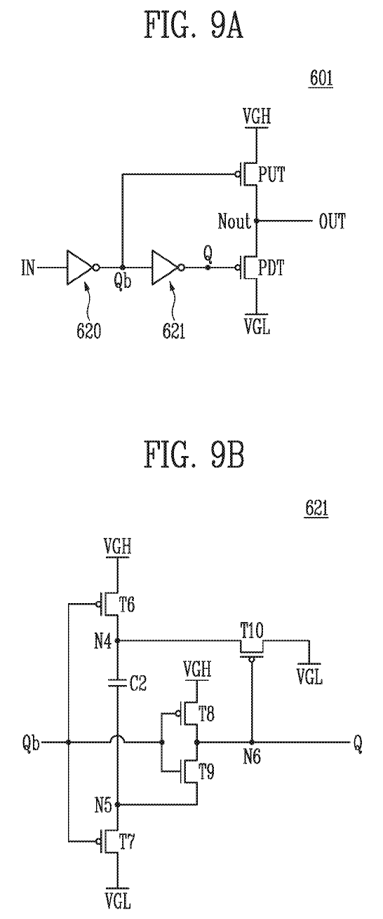

FIG. 9A is a block diagram illustrating an example of a buffer circuit 601 including voltage boosting circuits 620 and 621 according to some embodiments of the present disclosure. FIG. 9B is a schematic diagram of an equivalent circuit of the voltage boosting circuit 621 of FIG. 9A according to some embodiments of the present disclosure. Although FIG. 9B illustrates various components in a voltage boosting circuit according to some embodiments, embodiments according to the present disclosure are not limited thereto, and according to various embodiments, the voltage boosting circuit may include additional components or fewer components without departing from the spirit and scope of embodiments according to the present disclosure.

Referring to FIG. 9A, the buffer circuit 601 according to some embodiments of the present disclosure includes the pull-up transistor PUT, the pull-down transistor PDT, the first voltage boosting circuit 620, and the second voltage boosting circuit 621. The pull-up transistor PUT is connected between the first voltage VGH and the node Nout. The pull-down transistor PDT is connected between the node Nout and the second voltage VGL. The voltage of the node Nout constitutes an output signal OUT.

The input signal IN is applied to an input end of the first voltage boosting circuit 620. An output end of the first voltage boosting circuit 620 is connected to the node Qb. The node Qb is connected to an input end of the second voltage boosting circuit 621 and the gate electrode of the pull-up transistor PUT. An output end of the second voltage boosting circuit 621 is connected to the gate electrode of the pull-down transistor PDT through a node Q. According to some embodiments, the input signal IN may be the first clock signal CLK1 or the second clock signal CLK2. However, embodiments according to the present disclosure are not limited thereto, and various other signals may be applied to the buffer circuit as the input signal IN.

The first and second voltage boosting circuits 620 and 621 may serve as inverters in that the first and second voltage boosting circuits 620 and 621 logically invert the input signal. However, each of the first and second voltage boosting circuits 620 and 621 may output a signal having an amplitude of “2VGH-2VGL”.

On the other hand, when the input signal IN is a high-level signal, the pull-up transistor PUT is turned on and the pull-down transistor PDT is turned off, so that the voltage of the node Nout becomes a high level. Conversely, when the input signal IN is a low-level signal, the pull-up transistor PUT is turned off and the pull-down transistor PDT is turned on, so that the voltage of the output node Nout becomes a low level. That is, the output signal OUT composed of the voltage of the node Nout has the same phase as the input signal IN. When the input signal IN is the first clock signal CLK1, the output signal OUT may be used as the first clock signal of which the amplitude is amplified. On the other hand, when the input signal IN is the second clock signal CLK2, the output signal OUT may be used as the second clock signal of which the amplitude is amplified.

The first voltage boosting circuit 620 of FIG. 9A may be configured the same as the voltage boosting circuit 610 shown in FIG. 8B. The first voltage boosting circuit 620 outputs a signal of which the phase is inverted with the input signal IN and of which the amplitude is “2VGH-2VGL” to the node Qb.

Referring to FIG. 9B, the second voltage boosting circuit 621 may include sixth to tenth transistors T6 to T10 and a second capacitor C2. Among the sixth to tenth transistors T6 to T10, the sixth to eighth transistors T6 to T8 and the tenth transistor T10 may be P-type transistors, and the ninth transistor T9 may be an N-type transistor. The configuration of the circuit shown in FIG. 9B may be substantially the same as the voltage boosting circuit 610 shown in FIG. 8B. That is, the second voltage boosting circuit 621 outputs a boosting signal of which the phase is inverted with the signal of the node Qb and of which the amplitude is “2VGH-2VGL” to the node Q.

Thus, a signal is applied to the gate electrode of the pull-up transistor PUT, which is opposite in phase to the input signal IN and has an amplitude twice the amplitude of the input signal IN, i.e., “2VGH-2VGL”. On the other hand, a signal input to the gate electrode of the pull-down transistor PDT is a boosting signal having the same phase as the input signal IN and the amplitude twice the amplitude of the input signal IN, that is, “2VGH-2VGL”. Therefore, because the boosting signal with the amplified amplitude is applied to the gate electrode of the pull-down transistor PDT, distortion of the signal OUT of the node Nout is minimized or reduced.

As shown in FIG. 9B, the second voltage boosting circuit 621 may be implemented as a charge pump circuit using the second capacitor C2. However, embodiments according to the present disclosure are not limited thereto, and the second voltage boosting circuit 621 may be implemented in various ways other than the charge pump circuit.

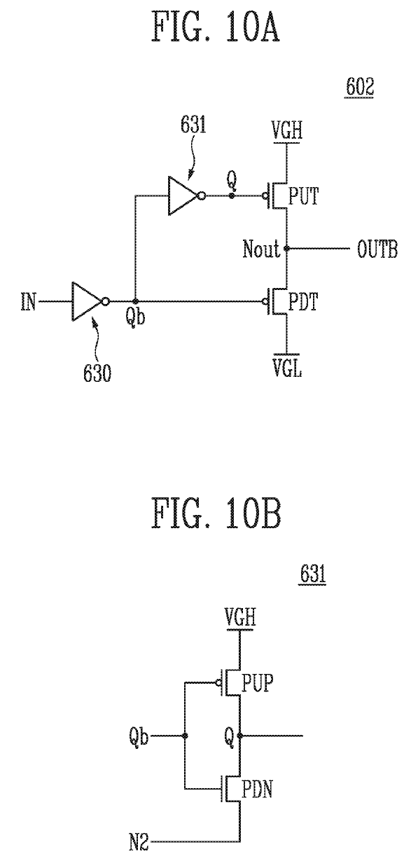

FIG. 10A is a block diagram illustrating an example of a buffer circuit 602 including a voltage boosting circuit 630 according to some embodiments of the present disclosure. FIG. 10B is a schematic diagram of an equivalent circuit of an inverter 631 of FIG. 10A according to some embodiments of the present disclosure. Although FIG. 10B illustrates various components in an inverter according to some embodiments, embodiments according to the present disclosure are not limited thereto, and according to various embodiments, the inverter may include additional components or fewer components without departing from the spirit and scope of embodiments according to the present disclosure.

Referring to FIG. 10A, the buffer circuit 602 according to some embodiments of the present disclosure includes the pull-up transistor PUT, the pull-down transistor PDT, the voltage boosting circuit 630, and the inverter 631. The pull-up transistor PUT is connected between the first voltage VGH and the node Nout. The pull-down transistor PDT is connected between the node Nout and the second voltage VGL. The voltage of the node Nout constitutes the output signal OUTB.

The input signal IN is applied to an input end of the voltage boosting circuit 630. An output end of the voltage boosting circuit 630 is connected to the gate electrode of the pull-down transistor PDT through the node Qb. The node Qb is also connected to an input end of the inverter 631, and an output end of the inverter 631 is connected to the gate electrode of the pull-up transistor PUT through the node Q.

When the input signal IN is a high-level signal, the pull-up transistor PUT is turned off and the pull-down transistor PDT is turned on, so that the voltage of the node Nout becomes a low level. Conversely, when the input signal IN is a low-level signal, the pull-up transistor PUT is turned on and the pull-down transistor PDT is turned off, so that the voltage of the output node Nout becomes a high level. That is, the output signal OUTB composed of the voltage of the node Nout is a logically inverted signal of the input signal IN. When the input signal IN is the first clock signal CLK1, the output signal OUTB may be used as the second clock signal CLK2. On the other hand, when the input signal IN is the second clock signal CLK2, the output signal OUTB may be used as the first clock signal CLK1. According to some embodiments, an additional inverter may be provided at the node Nout in FIG. 10A, so that the final output signal is in phase with the input signal IN.

The voltage boosting circuit 630 may serve as an inverter in that the voltage boosting circuit 630 logically inverts the input signal. However, the voltage boosting circuit 630 may not only invert the phase of the input signal but also amplify the amplitude of the input signal. That is, the voltage boosting circuit 630 generates a boosting signal with an amplified amplitude of the input signal IN, and outputs the generated boosting signal to the node Qb.

The voltage boosting circuit 630 of FIG. 10A may be configured the same as the voltage boosting circuit 610 shown in FIG. 8B. The voltage boosting circuit 630 outputs to the node Qb a boosting signal of which the phase is inverted with the input signal IN and has an amplitude of twice the amplitude of the input signal IN, i.e., “2VGH-2VGL”.

Referring to FIG. 10B, the inverter 631 may include a pull-up transistor PUP which is a P-type transistor and a pull-down transistor PDN which is an N-type transistor. The pull-up transistor PUP is connected between the first voltage VGH and the node Q, and a gate electrode of the pull-up transistor PUP is connected to the node Qb. The pull-down transistor PDN is connected between the node Q and the second node N2, and a gate electrode of the pull-down transistor PDN is connected to the node Qb.

When the input signal IN is at a logic high level, the voltage of the node Qb is at a low level. Therefore, in this case, the pull-up transistor PUP of the inverter 631 is turned on and the pull-down transistor PDN is turned off, and a voltage of the node Q becomes the first voltage VGH of a high level.

When the input signal IN is at a logic low level, the voltage of the node Qb is at a high level. Therefore, in this case, the pull-up transistor PUP of the inverter 631 is turned off and the pull-down transistor PDN is turned on. As described above with reference to FIG. 8B, when the input signal IN is at the logic low level, the voltage of the second node N2 becomes the second voltage VGL. Thus, the voltage of node Q will also be the second voltage VGL.

As a result, a signal which is opposite in phase to the input signal IN and has the same amplitude as the input signal IN is applied to the gate electrode of the pull-up transistor PUT. On the other hand, as a signal input to the gate electrode of the pull-down transistor PDT, a boosting signal is applied which is opposite in phase to the input signal IN and has an amplitude twice the amplitude of the input signal IN, i.e., “2VGH-2VGL”. Therefore, because the signal with the amplified amplitude is applied to the gate electrode of the pull-down transistor PDT, distortion of the signal OUTB of the node Nout is minimized or reduced.

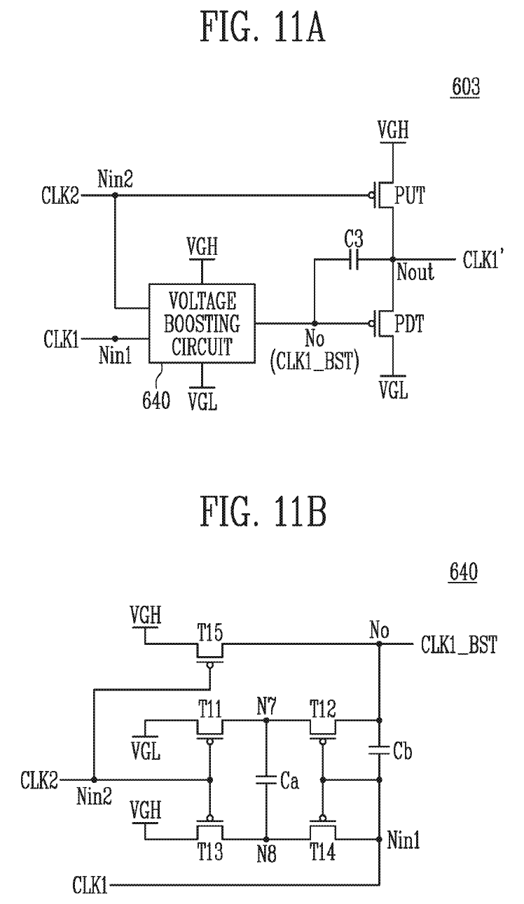

FIG. 11A is a block diagram illustrating an example of a buffer circuit 603 including a voltage boosting circuit 640 according to some embodiments of the present disclosure. FIG. 11B is a schematic diagram of an equivalent circuit of the voltage boosting circuit 640 of FIG. 11A according to some embodiments of the present disclosure. Although FIG. 11B illustrates various components in a voltage boosting circuit according to some embodiments, embodiments according to the present disclosure are not limited thereto, and according to various embodiments, the voltage boosting circuit may include additional components or fewer components without departing from the spirit and scope of embodiments according to the present disclosure.

Referring to FIG. 11A, the buffer circuit 603 according to some embodiments of the present disclosure includes the pull-up transistor PUT, the pull-down transistor PDT, the voltage boosting circuit 640, and a capacitor C3. The pull-up transistor PUT is connected between the first voltage VGH and the node Nout. The pull-down transistor PDT is connected between the node Nout and the second voltage VGL. The voltage of the node Nout constitutes the first clock signal CLK1’.

The voltage boosting circuit 640 may receive the first clock signal CLK1 and the second clock signal CLK2 through a first input node Nin1 and a second input node Nin2, respectively, and output a boosted first clock signal CLK1_BST through a node No. The node No is connected to the gate electrode of the pull-down transistor PDT. The voltage boosting circuit 640 receives the first voltage VGH and the second voltage VGL. Furthermore, the second input node Nin2 is connected to the gate electrode of the pull-up transistor PUT.

The capacitor C3 is connected between the node No and the node Nout. The boosted first clock signal CLK1_BST of the node No and the first clock signal CLK1’ of the node Nout are in-phase signals, and the capacitor C3 serves to assist the boosted first clock signal CLK1_BST output from the voltage boosting circuit 640 in having the better boosting characteristics. That is, the boosted first clock signal CLK1_BST has the better boosting characteristics when the capacitor C3 is connected between the node No and the node Nout than when the capacitor C3 is not connected between the nodes No and Nout. Accordingly, the capacitor C3 may be provided not only in the buffer circuit 603 shown in FIG. 11A, but also in the buffer circuits 600, 601, and 602 of FIGS. 8A, 9A, and 10A, respectively. Specifically, the capacitor C3 may be additionally connected between the node Qb and the node Nout in the buffer circuit 600 of FIG. 8A. In addition, the capacitor C3 may be additionally connected between the node Q and the node Nout in the buffer circuit 601 of FIG. 9A. The capacitor C3 may be additionally connected between the node Qb and the node Nout in the buffer circuit 602 of FIG. 10A.

Referring to FIG. 11B, aspects of the voltage boosting circuit 640 of FIG. 11A is shown as an example. The voltage boosting circuit 640 includes 11th to 15th transistors T11 to T15 and capacitors Ca and Cb. Although the 11th to 15th transistors T11 to T15 in FIG. 11B are shown to be P-type transistors, embodiments according to the present disclosure are not limited thereto. For example, at least one of the 11th to 15th transistors T11 to T15 may be replaced with an N-type transistor.

The 11th transistor T11 is connected between the second voltage VGL and a seventh node N7, and a gate electrode of the 11th transistor T11 is connected to the second input node Nin2 to receive the second clock signal CLK2. The 12th transistor T12 is connected between the seventh node N7 and the output node, that is, the node No, and a gate electrode of the 12th transistor T12 is connected to the first input node Nin1 to receive the first clock signal CLK1. The 13th transistor T13 is connected between the first voltage VGH and an eighth node N8, and a gate electrode of the 13th transistor T13 is connected to the second input node Nin2 to receive the second clock signal CLK2. The 14th transistor T14 is connected between the eighth node N8 and the first input node Nin1, and a gate electrode of the 14th transistor T14 is connected to the first input node Nin1 to receive the first clock signal CLK1. The 15th transistor T15 is connected between the first voltage VGH and the output node, that is, the node No, and a gate electrode of the 15th transistor T15 is connected to the second input node Nin2 to receive the second clock signal CLK2. The capacitor Ca is connected between the seventh node N7 and the eighth node N8. The capacitor Cb is connected between the node No and the first input node Nin1.

When a voltage of the first clock signal CLK1 is a high voltage and a voltage of the second clock signal CLK2 is a low voltage, the 11th, 13th, and 15th transistors T11, T13, and T15 are turned on, and the 12th and 14th transistors T12 and T14 are turned off. Accordingly, a voltage of the seventh node N7 becomes the second voltage VGL, and a voltage of the eighth node N8 becomes the first voltage VGH. Therefore, the voltage difference between opposite ends of the capacitor Ca becomes “VGL-VGH”. On the other hand, the voltage of the node No becomes the first voltage VGH, and the voltage difference between opposite ends of the capacitor Cb becomes substantially 0 V.

When the voltage of the first clock signal CLK1 is a low voltage and the voltage of the second clock signal CLK2 is a high voltage, the 11th, 13th, and 15th transistors T11, T13, and T15 are turned off, and the 12th and 14th transistors T12 and T14 are turned on. The voltage of the eighth node N8 becomes a low voltage of the first clock signal CLK1, for example, the second voltage VGL. To maintain the voltage difference “VGL-VGH” between opposite ends of the capacitor Ca, the voltage of the seventh node N7 becomes “2VGL-VGH”. When the voltage of the first clock signal CLK1 is a low voltage, the voltage of the seventh node N7 becomes the voltage of the node No.

In conclusion, when the voltage of the first clock signal CLK1 is a high voltage and the voltage of the second clock signal CLK2 is a low voltage, the voltage of the node No is the first voltage VGH, and when the voltage of the first clock signal CLK1 is a low voltage and the voltage of the second clock signal CLK2 is a high voltage, the voltage at the node No is “2VGL-VGH”. Therefore, the boosted first clock signal CLK1_BST appearing at the node No has the same phase as the first clock signal CLK1 and has an amplitude twice the amplitude of the first clock signal CLK1, that is, “2VGH-2VGL”.

As a result, the second clock signal CLK2 is applied to the gate electrode of the pull-up transistor PUT, and the boosted first clock signal CLK1_BST having the amplitude of “2VGH-2VGL” is applied to the gate electrode of the pull-down transistor PDT. Therefore, because the signal with the amplified amplitude is applied to the gate electrode of the pull-down transistor PDT, distortion of the first clock signal CLK1’ output to the node Nout is minimized or reduced.

As shown in FIG. 11B, the voltage boosting circuit 640 may be implemented as a charge pump circuit using the capacitors Ca and Cb. However, embodiments according to the present disclosure are not limited thereto, and the voltage boosting circuit 640 may be implemented in various ways other than the charge pump circuit.

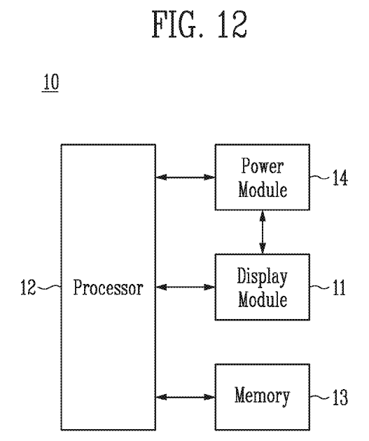

FIG. 12 is a block diagram of an electronic device 10 according to some embodiments of the present disclosure. Referring to FIG. 12, the electronic device 10 according to some embodiments may include a display module 11, a processor 12, memory 13, and a power module 14.

The processor 12 may include at least one of a central processing unit (CPU), an application processor (AP), a graphics processing unit (GPU), a communication processor (CP), an image signal processor (ISP), or a controller.

The memory 13 may store data information necessary for an operation of the processor 12 or the display module 11. When the processor 12 executes an application stored in the memory 13, an image data signal and/or an input control signal are transferred to the display module 11, and the display module 11 may process the received signal and output image information through a display screen.

The power module 14 may include a power supply module such as a power adapter or a battery device, and a power conversion module which converts power supplied by the power supply module to generate power necessary for an operation of the electronic device 10.

At least one of the above-described components of the electronic device 10 may be included in the display device according to the above-described embodiments. In addition, one or more of the individual modules which are functionally included in one module may be included in the display device, and others of the individual modules may be provided separately from the display device. For example, the display device includes the display module 11, and the processor 12, the memory 13, and the power module 14 may be provided in the form of other devices in the electronic device 10 other than the display device.

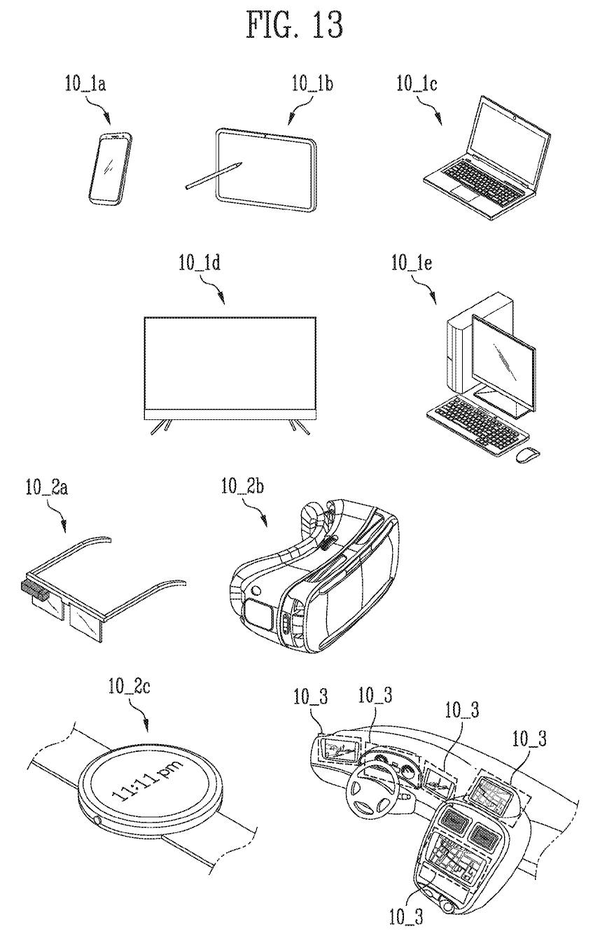

FIG. 13 shows schematic diagrams of electronic devices according to some embodiments of the present disclosure.

Referring to FIG. 13, various electronic devices to which the display device according to the embodiments is applied may include electronic devices for displaying an image such as a smartphone 10_1a, a tablet PC 10_1b, a laptop 10_1c, a television 10_1d, or a desk monitor 10_1e, as well as wearable electronic devices including display modules such as smart glasses 10_2a, a head-mounted display 10_2b, or a smart watch 10_2c, and automotive electronic devices 10_3 including display modules such as an automotive dashboard, a center fascia, a Center Information Display (CID) placed on a dashboard, or a room mirror display.

According to a buffer circuit, a display device, and an electronic device including the same according to embodiments of the present disclosure, distortion of a clock signal transmitted to a scan driver may be relatively reduced.

The foregoing referenced drawings and detailed descriptions of the present disclosure are mere examples of the present disclosure and are intended to illustrate the present disclosure but are not intended to limit the meaning or to restrict the scope of the present disclosure as claimed in the appended claims. Accordingly, those skilled in the art will understand that various modifications and other equivalent embodiments can be made from the foregoing referenced drawings and detailed descriptions. The true scope of technical protection of the present disclosure should therefore be determined by the technical spirit of the appended claims, and their equivalents.

What is claimed is:

1. A buffer circuit, comprising:
a pull-up transistor connected between a first voltage source and an output node;
a pull-down transistor connected between the output node and a second voltage source; and
at least one voltage boosting circuit configured to receive an input signal, to generate a boosting signal by amplifying an amplitude of the input signal, and to transmit the boosting signal to a gate electrode of the pull-down transistor.

2. The buffer circuit according to claim 1, wherein the pull-up transistor and the pull-down transistor are P-type transistors.

3. The buffer circuit according to claim 1, wherein the at least one voltage boosting circuit comprises a charge pump circuit.

4. The buffer circuit according to claim 3, wherein the at least one voltage boosting circuit comprises:
a first transistor connected between the first voltage source and a first node and having a gate electrode configured to receive the input signal;
a second transistor connected between a second node and the second voltage source and having a gate electrode configured to receive the input signal;
a first capacitor connected between the first node and the second node;
a third transistor connected between the first voltage source and a third node and having a gate electrode configured to receive the input signal;
a fourth transistor connected between the third node and the second node and having a gate electrode configured to receive the input signal; and
a fifth transistor connected between the first node and the second voltage source and having a gate electrode connected to the third node, and
wherein the third node is connected to the gate electrode of the pull-down transistor.

5. The buffer circuit according to claim 4, wherein the first transistor, the second transistor, the third transistor, and the fifth transistor are P-type transistors, and the fourth transistor is an N-type transistor.

6. The buffer circuit according to claim 3, wherein the at least one voltage boosting circuit comprises:
a first voltage boosting circuit configured to receive the input signal and to output a first boosting signal; and
a second voltage boosting circuit configured to receive the first boosting signal and to output a second boosting signal, and
wherein the first boosting signal is transmitted to a gate electrode of the pull-up transistor, and the second boosting signal is transmitted to the gate electrode of the pull-down transistor.

7. The buffer circuit according to claim 6, wherein the first voltage boosting circuit comprises:
a first transistor connected between the first voltage source and a first node and having a gate electrode configured to receive the input signal;
a second transistor connected between a second node and the second voltage source and having a gate electrode configured to receive the input signal;
a first capacitor connected between the first node and the second node;
a third transistor connected between the first voltage source and a third node and having a gate electrode configured to receive the input signal;
a fourth transistor connected between the third node and the second node and having a gate electrode configured to receive the input signal; and
a fifth transistor connected between the first node and the second voltage source and having a gate electrode connected to the third node, and
wherein the third node is connected to an input end of the second voltage boosting circuit.

8. The buffer circuit according to claim 7, wherein the second voltage boosting circuit comprises:
a sixth transistor connected between the first voltage source and a fourth node and having a gate electrode connected to the third node;
a seventh transistor connected between a fifth node and the second voltage source and having a gate electrode connected to the third node;
a second capacitor connected between the fourth node and the fifth node;
an eighth transistor connected between the first voltage source and a sixth node and having a gate electrode connected to the third node;
a ninth transistor connected between the sixth node and the fifth node and having a gate electrode connected to the third node; and
a tenth transistor connected between the fourth node and the second voltage source and having a gate electrode connected to the sixth node, and
wherein the sixth node is connected to the gate electrode of the pull-down transistor.

9. The buffer circuit according to claim 8, wherein the first transistor, the second transistor, the third transistor, the fifth transistor, the sixth transistor, the seventh transistor, the eighth transistor, and the tenth transistor are P-type transistors, and the fourth transistor and the ninth transistor are N-type transistors.

10. The buffer circuit according to claim 4, further comprising an inverter having an input end connected to the third node and an output end connected to a gate electrode of the pull-up transistor.

11. The buffer circuit according to claim 1, further comprising a third capacitor connected between the output node and the gate electrode of the pull-down transistor.

12. The buffer circuit according to claim 3, wherein the input signal comprises a first clock signal provided through a first input node and a second clock signal having a phase opposite to a phase of the first clock signal and provided through a second input node, and
wherein the at least one voltage boosting circuit comprises:
an eleventh transistor connected between the second voltage source and a seventh node and having a gate electrode connected to the second input node;
a twelfth transistor connected between the seventh node and the gate electrode of the pull-down transistor and having a gate electrode connected to the first input node;
a thirteenth transistor connected between the first voltage source and an eighth node and having a gate electrode connected to the second input node;
a fourteenth transistor connected between the eighth node and the first input node and having a gate electrode connected to the first input node;
a fifteenth transistor connected between the first voltage source and the gate electrode of the pull-down transistor and having a gate electrode connected to the second input node;
a fourth capacitor connected between the seventh node and the eighth node; and
a fifth capacitor connected between the first input node and the gate electrode of the pull-down transistor.

13. A display device, comprising:
a plurality of pixels;
a scan driver connected to the plurality of pixels through a plurality of scan lines;
a data driver connected to the plurality of pixels through a plurality of data lines configured to receive an image data signal and to transmit a corresponding analog voltage;
a driving controller configured to control operations of the scan driver and the data driver, and to provide a clock signal to the scan driver; and
a buffer circuit configured to compensate for distortion of the clock signal,
wherein the buffer circuit comprises:
a pull-up transistor connected between a first voltage source and an output node;
a pull-down transistor connected between the output node and a second voltage source; and
at least one voltage boosting circuit configured to receive the clock signal, to generage a boosting signal by amplifying an amplitude of the clock signal, and to transmit the boosting signal to a gate electrode of the pull-down transistor.

14. The display device according to claim 13, wherein the at least one voltage boosting circuit comprises:
a first transistor connected between the first voltage source and a first node and having a gate electrode to receive the clock signal;
a second transistor connected between a second node and the second voltage source and having a gate electrode configured to receive the clock signal;
a first capacitor connected between the first node and the second node;
a third transistor connected between the first voltage source and a third node and having a gate electrode configured to receive the clock signal;
a fourth transistor connected between the third node and the second node and having a gate electrode configured to receive the clock signal; and
a fifth transistor connected between the first node and the second voltage source and having a gate electrode connected to the third node, and
wherein the third node is connected to the gate electrode of the pull-down transistor.

15. The display device according to claim 13, wherein the at least one voltage boosting circuit comprises:
a first voltage boosting circuit configured to receive the clock signal and to output a first boosting signal; and
a second voltage boosting circuit configured to receive the first boosting signal and to output a second boosting signal, and
wherein the first boosting signal is transmitted to a gate electrode of the pull-up transistor, and the second boosting signal is transmitted to the gate electrode of the pull-down transistor.

16. The display device according to claim 15, wherein the first voltage boosting circuit comprises:
a first transistor connected between the first voltage source and a first node and having a gate electrode configured to receive the clock signal;
a second transistor connected between a second node and the second voltage source and having a gate electrode configured to receive the clock signal;
a first capacitor connected between the first node and the second node;
a third transistor connected between the first voltage source and a third node and having a gate electrode configured to receive the clock signal;
a fourth transistor connected between the third node and the second node and having a gate electrode configured to receive the clock signal; and
a fifth transistor connected between the first node and the second voltage source and having a gate electrode connected to the third node, and
wherein the third node is connected to an input end of the second voltage boosting circuit.

17. The display device according to claim 16, wherein the second voltage boosting circuit comprises:
a sixth transistor connected between the first voltage source and a fourth node and having a gate electrode connected to the third node;
a seventh transistor connected between a fifth node and the second voltage source and having a gate electrode connected to the third node;
a second capacitor connected between the fourth node and the fifth node;
an eighth transistor connected between the first voltage source and a sixth node and having a gate electrode connected to the third node;
a ninth transistor connected between the sixth node and the fifth node and having a gate electrode connected to the third node; and
a tentth transistor connected between the fourth node and the second voltage source and having a gate electrode connected to the sixth node, and
wherein the sixth node is connected to the gate electrode of the pull-down transistor.

18. The display device according to claim 13, wherein the buffer circuit further comprises a third capacitor connected between the output node and the gate electrode of the pull-down transistor.

19. The display device according to claim 13, wherein the clock signal comprises a first clock signal provided through a first input node and a second clock signal having a phase opposite to a phase of the first clock signal and provided through a second input node, and
wherein the at least one voltage boosting circuit comprises:
an eleventh transistor connected between the second voltage source and a seventh node and having a gate electrode connected to the second input node;
a twelfth transistor connected between the seventh node and the gate electrode of the pull-down transistor and having a gate electrode connected to the first input node;
a thirteenth transistor connected between the first voltage source and an eighth node and having a gate electrode connected to the second input node;
a fourteenth transistor connected between the eighth node and the first input node and having a gate electrode connected to the first input node;
a fifteenth transistor connected between the first voltage source and the gate electrode of the pull-down transistor and having a gate electrode connected to the second input node;
a fourth capacitor connected between the seventh node and the eighth node; and
a fifth capacitor connected between the first input node and the gate electrode of the pull-down transistor.

20. An electronic device, comprising:
a processor configured to provide input image data; and
a display device configured to display an image based on the input image data,
wherein the display device comprises:
a plurality of pixels;
a scan driver connected to the plurality of pixels through a plurality of scan lines;
a data driver connected to the plurality of pixels through a plurality of data lines configured to receive an image data signal and to transmit a corresponding analog voltage;
a driving controller configured to control operations of the scan driver and the data driver, and to provide a clock signal to the scan driver; and
a buffer circuit configured to compensate for distortion of the clock signal, and
wherein the buffer circuit comprises:
a pull-up transistor connected between a first voltage source and an output node;
a pull-down transistor connected between the output node and a second voltage source; and
at least one voltage boosting circuit configured to receive the clock signal, to generate a boosting signal by amplifying an amplitude of the clock signal, and to transmit the boosting signal to a gate electrode of the pull-down transistor.
